(19) United States
(12) Patent Application Publication
(10) Pub. No.: US 2026/0239597 A1
(43) Pub. Date: Aug. 13, 2026

(54) DRAM CELL STRUCTURE, THREE-DIMENSIONAL DRAM ARRAY STRUCTURE, AND SEMICONDUCTOR DEVICE INCLUDING THE SAME

(71) Applicant: Tsinghua University, Beijing (CN)

(72) Inventor: Liyang Pan, Beijing (CN)

(21) Appl. No.: 19/459,895

(22) Filed: Jan. 26, 2026

(30) Foreign Application Priority Data
Feb. 12, 2025 (CN) CN 202510155683.6
Feb. 12, 2025 (CN) CN 202510155949.7

(51) Int. Cl. H10B 12/00

(52) U.S. Cl. CPC H10B 12/00

(57) ABSTRACT

A DRAM cell structure is provided, including: first and second transistors, each having a channel with tubular structure and a gate surrounding the channel, sequentially disposed in a vertical direction and electrically connected in parallel; a storage capacitor having a tubular structure, disposed in the vertical direction between the first and second transistors, having an inner electrode connected to first sources/drains of the first and second transistors, and an outer electrode connected to a source line; and a bit line within the tubular structure collectively formed by the first and second transistors and the storage capacitor, and connecting to second sources/drains of the first and second transistors. The inner electrode of the storage capacitor and the source/drain regions and channel regions of the two transistors are formed by the same semiconductor material layer, thus having simple structure and good switching performance.

### CROSS-REFERENCE TO RELATED APPLICATIONS

This application claims priority to Chinese Patent Application Nos. CN 202510155683.6 and CN202510155949.7 both filed Feb. 12, 2025, each of which is incorporated by reference in its entirety.

### TECHNICAL FIELD

The present disclosure relates to the field of semiconductor technology. Specifically, the present disclosure relates to dynamic random access memory (DRAM) cell structures, and three-dimensional DRAM array structures, and semiconductor device including the same.

### BACKGROUND

Since Intel Corporation invented Dynamic Random Access Memory (DRAM) in the 1970s, DRAM has been widely used in various computing or control electronic circuit systems.

A DRAM cell circuit typically consist of a selection transistor for selection and a storage capacitor for storing charge (1T1C structure). In a DRAM cell structure using traditional planar structure based horizontal transistor, for example, Metal Oxide Semiconductor Field Effect Transistor (MOSFET), to realize selection transistor, the source, gate, and drain of the transistor are arranged horizontally parallel to the substrate surface. Since the source, gate, and drain of the transistor each occupy an independent area in the horizontal direction, the miniaturization of the DRAM cell circuit structure is limited by the gate length and contact size, which cannot meet the needs of continuous miniaturization of DRAM devices, and thus limits the further increase in the integration and bandwidth of DRAM devices.

Therefore, vertical DRAM cell structures have been proposed in recent years, in which the source, gate, and drain of transistors are disposed in the vertical direction perpendicular to the substrate surface, requiring no additional area and facilitating the miniaturization of DRAM array structures. Furthermore, by vertically stacking of multiple layers of DRAM cells to form a three-dimensional DRAM array, memory integration density can be further improved.

DRAM manufacturing is a highly competitive industry. The industry continuously needs to reduce the size of individual cells and increase memory cell density, thereby allowing a single memory chip to hold more memory.

The above information disclosed in this background section is only for understanding the background of the inventive concept and may therefore contain information that does not constitute prior art.

### SUMMARY

To address the aforementioned problems in the prior art, the present disclosure proposes a novel vertical dynamic random access memory (DRAM) cell structure.

According to one aspect of the present disclosure, a dynamic random access memory (DRAM) cell structure is provided, comprising: a first transistor and a second transistor, each having a channel with tubular structure and a gate surrounding the channel, sequentially disposed in a vertical direction and electrically connected in parallel; a storage capacitor having a tubular structure, disposed in the vertical direction between the first and second transistors, having an inner electrode connected to first sources/drains of the first transistor and the second transistor, and having an outer electrode connected to a source line; and a bit line extending in the vertical direction within the tubular structure collectively formed by the first and second transistors as well as the storage capacitor, and connecting to second sources/drains of the first and second transistors.

In the DRAM cell structure according to the present disclosure, a first word line extends along a first horizontal direction and is connected to the gate of a first transistor, and a second word line extends along a first horizontal direction and is connected to the gate of a second transistor, the first word line and the second word line overlapping in the vertical direction.

The DRAM cell structure according to the present disclosure includes two mirror-disposed transistors and a storage capacitor in the vertical direction, wherein the inner electrode of the storage capacitor and the source/drain and channel regions of the two transistors are formed by the same semiconductor material layer. Therefore, it has the advantages such as simple structure and good switching performance, and is beneficial for stacking in the vertical direction to form a three-dimensional multilayer memory array.

To address the aforementioned problems in the prior art, the present disclosure also proposes a novel three-dimensional DRAM array structure and a semiconductor device including the same.

According to one aspect of the present disclosure, a three-dimensional DRAM array structure is provided, comprising: a plurality of DRAM cell structures arranged in L layers, M rows, and N columns, where L, M, and N are natural numbers greater than 1, each of the plurality of DRAM cell structures including: a first transistor and a second transistor, each having a channel with tubular structure and a gate surrounding the channel, and sequentially disposed in a vertical direction and electrically connected in parallel, and a storage capacitor having a tubular structure, disposed in the vertical direction between the first and second transistors, having an inner electrode connected to first sources/drains of the first and second transistors, and having an outer electrode connected to a source line; M×N bit lines extending respectively in the vertical direction within the tubular structure collectively formed by the first and second transistors as well as the storage capacitor in the M rows and N columns of the DRAM cell structures, and connecting to second sources/drains of the first and second transistors in the M rows and N columns of the DRAM cell structures; L×M first word lines extending along a first horizontal direction and respectively connecting to the gates of the first transistors in the L layers and M rows of the DRAM cell structures; and L×M second word lines extending along the first horizontal direction and respectively connecting to the gates of the second transistors in the L layers and M rows of the DRAM cell structures.

According to another aspect of the present disclosure, a semiconductor device is provided, comprising: a three-dimensional DRAM array structure according to the above aspect of the present disclosure; and a circuit substrate including a plurality of circuits, wherein the three-dimensional DRAM array structure is disposed on the circuit substrate.

The DRAM cell structure constituting the DRAM array structure according to the present disclosure includes two transistors and a storage capacitor mirror-disposed in the vertical direction, wherein the inner electrode of the storage capacitor and the source/drain and channel regions of the two transistors are formed by the same semiconductor material layer, thus having the advantages of simple structure and good switching performance.

Furthermore, the DRAM array structure according to the present disclosure can achieve three-dimensional vertical integration by stacking multiple layers of DRAM cells, thereby increasing integration density. Additionally, the DRAM array structure according to the present disclosure can be stacked on a circuit substrate including a plurality of circuits, thus enabling system-level three-dimensional vertical integration and significantly reducing the area overhead of the circuit system.

However, the effects of the present disclosure are not limited to those described above, and various extensions can be made without departing from the spirit and scope of the present disclosure. It should be understood that the foregoing general description and the following detailed description are exemplary and explanatory, and are intended to provide further illustration of the claimed disclosure.

### BRIEF DESCRIPTION OF THE DRAWINGS

The drawings, which are included to provide a further understanding of the present disclosure and are incorporated in and constitute a part of this specification, illustrate exemplary embodiments of the present disclosure and, together with the specification, serve to explain the inventive concept.

FIG. 1 is an equivalent circuit diagram illustrating a dynamic random access memory (DRAM) cell structure according to an embodiment of the present disclosure.

FIG. 2 is a perspective view illustrating a DRAM cell structure according to an embodiment of the present disclosure.

FIG. 3 is a top view illustrating a DRAM cell structure according to an embodiment of the present disclosure.

FIG. 4 is a cross-sectional view illustrating a DRAM cell structure according to an embodiment of the present disclosure, taken along line AA′ in FIG. 3.

FIG. 5 is a cross-sectional view illustrating a DRAM cell structure according to an embodiment of the present disclosure, taken along line BB′ in FIG. 3.

FIG. 6 is a cross-sectional view illustrating a DRAM cell structure according to an embodiment of the present disclosure, taken along line CC′ in FIG. 4.

FIG. 7 is a cross-sectional view illustrating a DRAM cell structure according to an embodiment of the present disclosure, taken along line DD′ in FIG. 4.

FIG. 8 is a top view illustrating a DRAM cell structure according to another embodiment of the present disclosure.

FIG. 9 is a cross-sectional view illustrating a DRAM cell structure according to another embodiment of the present disclosure, taken along line AA′ in FIG. 8.

FIG. 10 is a cross-sectional view illustrating a DRAM cell structure according to another embodiment of the present disclosure, taken along line BB′ in FIG. 8.

FIG. 11 is a cross-sectional view illustrating a DRAM cell structure according to another embodiment of the present disclosure, taken along line CC′ in FIG. 9.

FIG. 12 is a cross-sectional view illustrating a DRAM cell structure according to another embodiment of the present disclosure, taken along line DD′ in FIG. 9.

FIG. 13 is a top view illustrating a DRAM cell structure according to yet another embodiment of the present disclosure.

FIG. 14 is a cross-sectional view illustrating a DRAM cell structure according to yet another embodiment of the present disclosure, taken along line AA′ in FIG. 13.

FIG. 15 is a cross-sectional view illustrating a DRAM cell structure according to yet another embodiment of the present disclosure, taken along line BB′ in FIG. 13.

FIG. 16 is a cross-sectional view of a DRAM cell structure according to yet another embodiment of the present disclosure, taken along line CC′ in FIG. 14.

FIG. 17 is a cross-sectional view illustrating a DRAM cell structure according to yet another embodiment of the present disclosure, taken along line DD′ in FIG. 14.

FIG. 18 is an equivalent circuit diagram illustrating a DRAM array structure formed by the DRAM cell structure shown in FIG. 1 according to an embodiment of the present disclosure.

FIG. 19 is an equivalent circuit diagram illustrating the DRAM cell structure of the first row of the DRAM array structure according to an embodiment of the present disclosure shown in FIG. 18.

FIG. 20 is a schematic perspective view illustrating the first layer, first row of DRAM cell structure of the DRAM array structure according to an embodiment of the present disclosure shown in FIG. 18.

FIG. 21 is a top view of a partial DRAM array structure illustrating the DRAM array structure according to an embodiment of the present disclosure as shown in FIG. 18.

FIG. 22 is a cross-sectional view illustrating a DRAM array structure according to an embodiment of the present disclosure, taken along line AA′ in FIG. 21.

FIG. 23 is a cross-sectional view of a DRAM array structure according to an embodiment of the present disclosure, taken along line BB′ in FIG. 21.

FIG. 24 is a cross-sectional view of a DRAM array structure according to an embodiment of the present disclosure, taken along line CC′ in FIG. 22.

FIG. 25 is a cross-sectional view illustrating a DRAM array structure according to an embodiment of the present disclosure, taken along line DD′ in FIG. 22.

FIG. 26 is an equivalent circuit diagram illustrating a DRAM array structure with alternative configurations of word line according to an embodiment of the present disclosure.

FIG. 27 is an equivalent circuit diagram illustrating a DRAM array structure with an alternative configuration of bit line according to an embodiment of the present disclosure.

FIG. 28 is a schematic cross-sectional view illustrating a semiconductor device according to an embodiment of the present disclosure.

FIG. 29 is a schematic block diagram illustrating a semiconductor device according to an embodiment of the present disclosure.

### DETAILED DESCRIPTION

In the following description, for the purpose of explanation, many specific details are set forth in order to provide a thorough understanding of exemplary embodiments or implementations of the present disclosure. As used herein, “embodiment” and “implementation” are interchangeable words, and are non-limiting examples of the device or method employing one or more of concepts of the invention disclosed herein. However, it is obvious that the exemplary embodiments may be embodied without these specific details or with one or more equivalent arrangements. In other instances, well-known structures and devices are shown in block diagram in order to avoid unnecessarily obscuring the exemplary embodiments. In addition, the exemplary embodiments may be different, but need not be exclusive. For example, certain shapes, configurations, and characteristics of the exemplary embodiments may be used or implemented in other exemplary embodiments without departing from the spirit of the present invention.

Unless otherwise stated, the illustrated exemplary embodiments should be understood to provide exemplary features with varying details of some of the ways in which the concepts of the invention may be practiced. Therefore, unless otherwise stated, features, components, modules, layers, films, panels, regions and/or aspects, etc. (hereinafter individually or collectively referred to as “elements”) of various embodiments may be additionally combined, separated, interchanged and/or rearranged without departing from the concepts of the invention.

For the purposes of the present disclosure, “at least one of X, Y, and Z” and “at least one selected from the set consisting of X, Y, and Z” may be interpreted as X only, Y only, Z only, or any combination of two or more of X, Y, and Z, for example, XYZ, XYY, YZ, and ZZ. As used herein, the term “and/or” includes any and all combinations of one or more of related items listed.

Although the terms “first,” “second,” etc. may be used herein to describe various types of elements, these elements should not be limited by these terms. These terms are used to distinguish one element from another. Thus, a first element discussed below could be referred to as a second element without departing from the teaching of the present disclosure.

The terminology used herein is for the purpose of describing particular embodiments, and not intended to be limiting. As used herein, the singular forms “a”, “an” and “the” are intended to also include the plural form, unless the context clearly indicates otherwise. In addition, the terms “comprises” and/or “comprising” when used herein specify the presence of stated features, integers, steps, operations, elements, components, and/or sets thereof, but does not exclude the presence or addition of one or more other features, integers, steps, operations, elements, components, and/or sets thereof. As used herein, the terms “substantially”, “about” and other similar terms are used as terms of approximation rather than terms of degree, and are thus utilized to account for inherent deviations in measured, calculated and/or provided values as appreciated by those skilled in the art.

Unless otherwise defined, all terms (including technical terms and scientific terms) used herein have the same meaning as those collectively understood by those skilled in the art to which the present disclosure belongs. Terms, such as those defined in collectively used dictionaries, should be interpreted as having a meaning that is consistent with their meaning in the context of the relevant art and will not be interpreted in an idealized or overly formal sense unless expressly defined herein.

Various embodiments of the present disclosure will now be described more fully below with reference to the drawings. However, the present disclosure may be implemented in many different ways and should not be construed as limited to the embodiments set forth herein. Rather, these embodiments are provided so that the present disclosure will be exhaustive and complete and will fully convey the scope of the present disclosure to those skilled in the art. The same reference numeral throughout indicates the same component. Furthermore, in the drawings, for clarity of illustration, the parts are not necessarily drawn in ratio, and the ratios and sizes of the parts may be exaggerated.

The dynamic random access memory (DRAM) cell structure according to embodiments of the present disclosure will now be described in detail with reference to the drawings.

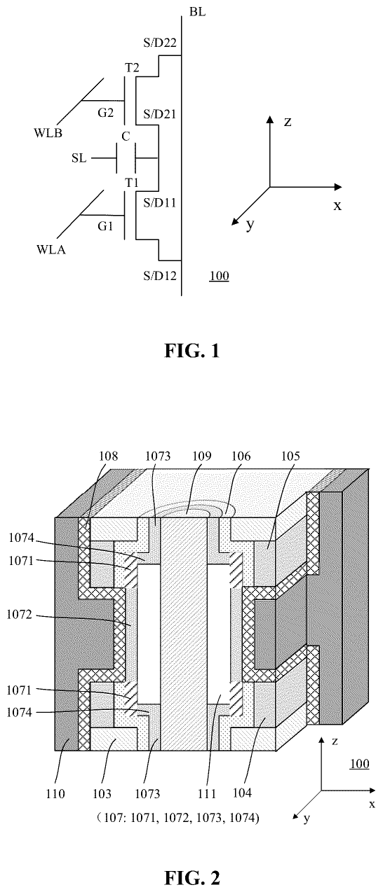

FIG. 1 shows an equivalent circuit diagram of a DRAM cell structure 100 according to an embodiment of the present disclosure.

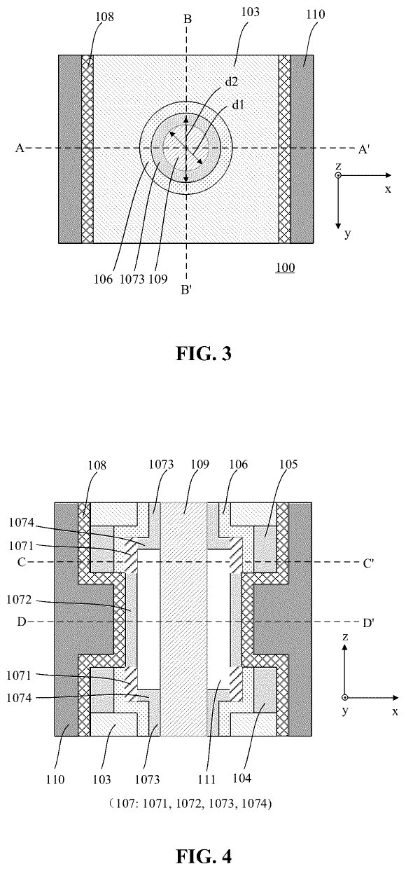

As shown in FIG. 1, the DRAM cell structure 100 according to an embodiment of the present disclosure can adopt a 2T1C (i.e., two selection transistors and one storage capacitor) cell structure. Specifically, the DRAM cell structure 100 may include two transistors, namely a first transistor T1 and a second transistor T2, which are sequentially disposed in the vertical direction (z direction) and electrically connected in parallel. Both the first and second transistors T1 and T2 may have a channel with tubular structure (as described below with reference to FIGS. 2 to 17) and serve as selection transistors of the DRAM cell structure 100.

According to an embodiment of the present disclosure, the first source/drain S/D11 of the first transistor T1 and the first source/drain S/D21 of the second transistor T2 are collectively connected to one plate (inner electrode) of the memory capacitor C, and the second source/drain S/D12 of the first transistor T1 and the second source/drain S/D22 of the second transistor T2 are collectively connected to the bit line BL. According to an embodiment of the present disclosure, the bit line BL can extend in the vertical direction (z direction). Furthermore, according to an embodiment of the present disclosure, the gate G1 of the first transistor T1 can be connected to the first word line WLA, and the gate G2 of the second transistor T2 can be connected to the second word line WLB. According to an embodiment of the present disclosure, the first word line WLA and the second word line WLB can extend along a first horizontal direction (y direction) and overlap in the vertical direction (z direction). According to an embodiment of the present disclosure, the first word line WLA and the second word line WLB can be shorted together. Alternatively, according to an embodiment of the present disclosure, the first word line WLA and the second word line WLB can also not be shorted together to control the first transistor T1 and the second transistor T2 separately.

Furthermore, according to embodiments of the present disclosure, the other plate (outer electrode) of the storage capacitor C can be connected to the source line SL. Those skilled in the art will recognize that in a DRAM array structure composed of the DRAM cell structure 100 according to the present disclosure, the source lines SL of all DRAM cell structures can be connected together either collectively or in groups, therefore, the source line SL can also be referred to herein as a “common electrode”.

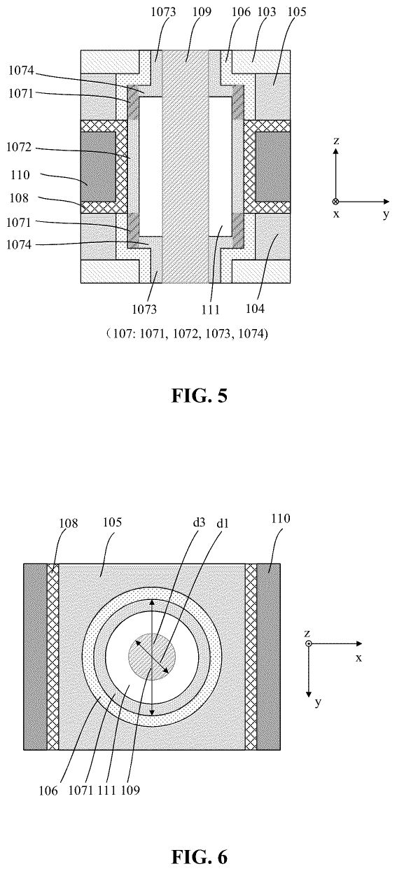

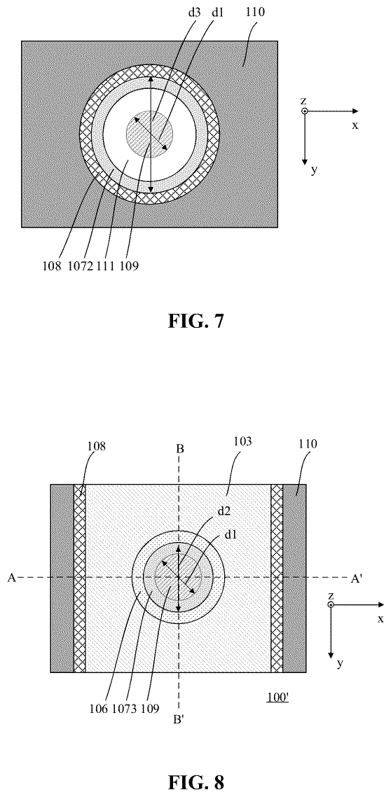

FIG. 2 shows a perspective view of a DRAM cell structure 100 according to an embodiment of the present disclosure. FIG. 3 shows a top view of a DRAM cell structure 100 according to an embodiment of the present disclosure. FIG. 4 shows a cross-sectional view of a DRAM cell structure 100 according to an embodiment of the present disclosure, taken along line AA′ in FIG. 3. FIG. 5 shows a cross-sectional view of a DRAM cell structure 100 according to an embodiment of the present disclosure, taken along line BB′ in FIG. 3. FIG. 6 shows a cross-sectional view of a DRAM cell structure 100 according to an embodiment of the present disclosure, taken along line CC′ in FIG. 4. FIG. 7 shows a cross-sectional view of a DRAM cell structure 100 according to an embodiment of the present disclosure, taken along line DD′ in FIG. 4.

As shown in FIGS. 2 to 7, according to an embodiment of the present disclosure, the DRAM cell structure 100 may include a bit line hole (for example, a hole with a circular cross section located at the center, as shown in FIGS. 3, 6 and 7) extending in the vertical direction (z direction), and a common electrode trench (trenches on both sides of the bit line hole located at the center, as shown in FIGS. 2, 3, 4, 6 and 7) extending in the first horizontal direction (y direction) and extending through the DRAM cell structure 100 in the vertical direction (z direction).

As shown in FIGS. 2 to 7, according to embodiments of the present disclosure, the DRAM cell structure 100 may include conductor lines 109 disposed in bit line holes. The conductor lines 109 extend in the vertical direction (z direction) and can be used as bit line BL of the DRAM cell structure 100 shown in FIG. 1. According to embodiments of the present disclosure, the materials used to form the conductor lines 109 may include tungsten silicide (WSi), tungsten nitride (WN), tungsten (W), titanium (Ti), titanium nitride (TiN), tantalum (Ta), tantalum nitride (TaN), or combinations thereof. In particular, according to embodiments of the present disclosure, the conductor lines 109 may have a cylindrical shape extending in the vertical direction (z direction). For example, as shown in FIGS. 3, 6, and 7, the conductor lines 109 may be cylinders having a first diameter d1.

As shown in FIGS. 2 to 7, according to embodiments of the present disclosure, the DRAM cell structure 100 may include a semiconductor material layer 107 with a tubular structure and a first isolation material layer 111 surrounding the conductor line 109, which are disposed in a bit line hole. Specifically, as shown more clearly in FIGS. 4 and 5, the upper and lower ends of the semiconductor material layer 107 directly contact the conductor line 109, and the middle portion of the semiconductor material layer 107 is separated from the conductor line 109 by the first isolation material layer 111. In other words, according to embodiments of the present disclosure, both the semiconductor material layer 107 and the first isolation material layer 111 have a tubular structure surrounding the conductor line 109. Although the tubular structure has a circular cross-section in FIGS. 3, 6, and 7, the present disclosure is not limited thereto. Those skilled in the art will recognize that the tubular structure may also have other arbitrary shapes of cross-sections, such as elliptical, square, or rectangular cross-sections, in which case the cross-sectional shape of the conductor line 109 can be adjusted accordingly.

According to embodiments of the present disclosure, the material used to form the first isolation material layer 111 can be a dielectric material collectively used in integrated circuit processes, for example, silicon oxide, silicon nitride, silicon oxynitride, aluminum oxide, glass phosphate, or a combination thereof. According to embodiments of the present disclosure, the material used to form the first isolation material layer 111 can also be a low-K material. The low-K material can have a lower dielectric constant than silicon oxide. Silicon oxide can have a dielectric constant of about 3.9, and the first isolation material layer 111 can include a low-K material with a dielectric constant of about 3.9 or lower. According to embodiments of the present disclosure, low-K materials can include porous silicon oxide (SiO₂), organosilicon, fluorinated silicon glass (FSG), silsesquioxane (HSQ), silicon carbide (SiCOH), or polymer materials such as parylene and polyimide (PI). According to embodiments of the present disclosure, the material used to form the first isolation material layer 111 can also be a combination of the above-mentioned dielectric materials and the above-mentioned low-K materials.

According to embodiments of the present disclosure, the material used to form the semiconductor material layer 107 can be a semiconductor thin film material, for example, monocrystalline silicon, polycrystalline silicon, amorphous silicon, silicon-germanium compound, compound semiconductor, oxide semiconductor, sulfide semiconductor, graphene, or a combination thereof. According to embodiments of the present disclosure, the material used to form the semiconductor material layer 107 can be an oxide semiconductor material, for example, indium gallium zinc oxide (IGZO), indium oxide (InO), zinc oxide (ZnO), indium tungsten oxide (InWO), or indium aluminum oxide (InAlO) in different proportions. In particular, according to embodiments of the present disclosure, the semiconductor material layer 107 may include a single layer of IGZO or a stack of multiple layers of IGZO with different proportions.

Furthermore, according to embodiments of the present disclosure, as described in more detail below, the semiconductor material layer 107 can form the source/drain regions and channel regions of the first transistor T1 and the second transistor T2 as shown in FIG. 1, wherein the source/drain regions of the first transistor T1 and the second transistor T2 correspond to the first source/drain S/D11 and the second source/drain S/D12 of the first transistor T1 and the first source/drain S/D21 and the second source/drain S/D22 of the second transistor T2. It should be noted that the source/drain regions described from a structural perspective are equivalent to the source/drains described from a circuit perspective. Furthermore, according to embodiments of the present disclosure, the semiconductor material layer 107 can also form the inner electrode of the storage capacitor C as shown in FIG. 1. Therefore, according to embodiments of the present disclosure, the storage capacitor C can also have a tubular structure.

As shown in FIGS. 2 to 7, according to an embodiment of the present disclosure, the DRAM cell structure 100 may include two first dielectric layers 106 disposed in bit line holes, respectively surrounding the upper and lower ends of a semiconductor material layer 107. According to an embodiment of the present disclosure, the two first dielectric layers 106 may respectively form the gate dielectrics of the first transistor T1 and the second transistor T2 as shown in FIG. 1. As shown in FIGS. 4 and 5, according to an embodiment of the present disclosure, the first dielectric layer 106 may also have a tubular structure with a bent cross-section. In other words, as shown in FIGS. 2 to 5, in a cross-section along the vertical direction (z direction), the first dielectric layer 106 may have a thinner first portion near the end of the conductor line 109 and a thicker second portion and away from the end of the conductor line 109 relative to the first portion, and the first portion and second portion may be connected by a connecting portion in horizontal direction. According to embodiments of the present disclosure, the material used to form the first dielectric layer 106 may include, for example, silicon oxide (SiO₂), silicon oxynitride (SiON), aluminum oxide (Al₂O₃), hafnium oxide (HfO₂), zirconium oxide (ZrO₂), lanthanum oxide (La₂O₃), or combinations thereof.

Therefore, according to the embodiments of the present disclosure, both the first transistor T1 and the second transistor T2 are formed to have a tubular structure and each has a tubular channel.

As shown in FIGS. 2 to 7, according to an embodiment of the present disclosure, the DRAM cell structure 100 may include a below first gate layer 104 and an above second gate layer 105, which are disposed respectively surrounding thicker second portions of the upper and lower first dielectric layers 106. As shown in FIGS. 2 and 6, according to an embodiment of the present disclosure, the first gate layer 104 and the second gate layer 105 may have a slat shape with a central hole. According to an embodiment of the present disclosure, the first gate layer 104 may correspond to the gate G1 of the first transistor T1 shown in FIG. 1, and the second gate layer 105 may correspond to the gate G2 of the second transistor T2 shown in FIG. 1. Furthermore, as shown in FIGS. 2, 3, and 5, according to an embodiment of the present disclosure, the first gate layer 104 may extend in a first horizontal direction (y direction) to further correspond to the first word line WLA connected to the first gate G1 of the first transistor T1 as shown in FIG. 1. Accordingly, according to embodiments of the present disclosure, the second gate layer 105 may extend in a first horizontal direction (y direction) to further correspond to the second word line WLB connected to the gate G2 of the second transistor T2 as shown in FIG. 1. According to embodiments of the present disclosure, the first word line WLA and the second word line WLB may be led out from the distal end in the first horizontal direction (y direction). As shown in FIGS. 2 to 7, according to an embodiment of the present disclosure, the first gate layer 104 forms the gate G1 surrounding the channel of the first transistor T1, and the second gate layer 105 forms the gate G2 surrounding the channel of the second transistor T2.

Therefore, according to embodiments of the present disclosure, the DRAM cell structure 100 may have a bit line BL extending in the vertical direction (z direction), and a first word line WLA and a second word line WLB extending in the first horizontal direction (y direction). According to embodiments of the present disclosure, the bit line BL of the DRAM cell structure 100 may extend in the vertical direction within a tubular structure collectively formed by the first transistor T1 and the second transistor T2, as well as the storage capacitor C. Furthermore, according to embodiments of the present disclosure, the first gate layer 104 and the second gate layer 105 corresponding to the first word line WLA and the second word line WLB of the DRAM cell structure 100 may overlap in the vertical direction (z direction).

Furthermore, according to embodiments of the present disclosure, the materials used to form the first gate layer 104 and the second gate layer 105 may include titanium nitride (TiN), tantalum nitride (TaN), aluminum titanium carbide (TiAlC), aluminum (Al), copper (Au), titanium (Ti), palladium (Pd), molybdenum (Mo), platinum (Pt), tungsten (W), doped polycrystalline/amorphous silicon, indium tin oxide (ITO), indium zinc oxide (IZO), or combinations thereof.

As shown in FIGS. 2 to 7, according to embodiments of the present disclosure, the DRAM cell structure 100 may include two second isolation material layers 103 configured to respectively surround a thinner first portion of the above and below first dielectric layer 106. As shown in FIGS. 2 and 3, according to embodiments of the present disclosure, the second isolation material layer 103 may have a slat shape with a central hole. According to embodiments of the present disclosure, the material used to form the second isolation material layer 103 may include silicon oxide (SiO₂), silicon nitride (SiN), silicon oxynitride (SiON), silicon carbide (SiCOH), or aluminum oxide (Al₂O₃). According to embodiments of the present disclosure, the first isolation material layer 111 and the second isolation material layer 103 may be formed of the same or different isolation materials.

As shown in FIGS. 4 and 5, according to an embodiment of the present disclosure, as described above, the semiconductor material layer 107 may include, along the vertical direction (z direction), a first portion 1071, indicated by shading, forming the channel regions of the first and second transistors T1 and T2 shown in FIG. 1, and a second portion 1072 among the first portion 1071 forming the first source/drain region of the first transistor T1 (corresponding to the first source/drain S/D11 of the first transistor T1), the first source/drain region of the second transistor T2 (corresponding to the first source/drain S/D21 of the second transistor T2), and the inner electrode of the memory capacitor C. Therefore, according to an embodiment of the present disclosure, the first source/drain S/D11 of the first transistor T1 and the first source/drain S/D21 of the second transistor T2 are connected together with the inner electrode of the memory capacitor C. According to an embodiment of the present disclosure, the first portion 1071 and the second portion 1072 of the semiconductor material layer 107 are separated from the conductor line 109 (bit line BL) by a first isolation material layer 111 surrounding the conductor line 109 (bit line BL).

According to embodiments of the present disclosure, the doping type, doping concentration, and/or atomic composition ratio of the second portion 1072 of the semiconductor material layer 107 can be changed by material modification processes such as doping and etching, so that it has better conductivity as the inner electrode of the memory capacitor C. That is, according to embodiments of the present disclosure, the first portion 1071 and the second portion 1072 of the semiconductor material layer 107 can have different doping types, doping concentrations, and/or atomic composition ratios. According to embodiments of the present disclosure, when the semiconductor material layer 107 is an IGZO oxide semiconductor, all or part of the gallium (Ga) atoms in the second portion 1072 can be removed by, for example, etching to improve its conductivity, or part of the oxygen (O) atoms in the second portion 1072 can be removed by, for example, etching to form metal atom interstitials or oxygen atom vacancies to improve its conductivity.

Furthermore, as shown in FIGS. 4 and 5, according to an embodiment of the present disclosure, as described above, the semiconductor material layer 107 may further include, along the vertical direction (z direction), a third portion 1073 contacting the both ends of the conductor line 109, serving as the second source/drain region (corresponding to the second source/drain S/D12 of the first transistor T1) of the first transistor T1 as shown in FIG. 1 and the second source/drain region (corresponding to the second source/drain S/D22 of the second transistor T2) the second transistor T2 and a first horizontal connecting portion 1074 connecting the first portion 1071 and the third portion 1073. Therefore, according to an embodiment of the present disclosure, the third portion 1073 of the semiconductor material layer 107 contacts the conductor line 109, such that the second source/drain S/D12 of the first transistor T1 and the second source/drain S/D22 of the second transistor T2, corresponding to the third portion 1073 of the semiconductor material layer 107, are connected to the bit line BL corresponding to the conductor line 109.

As shown in FIG. 3, according to an embodiment of the present disclosure, the third portion 1073 of the semiconductor material layer 107 with a tubular structure may have a second diameter d2, which is larger than the first diameter d1 of the conductor line 109. Furthermore, as shown in FIG. 3 to FIG. 7, according to an embodiment of the present disclosure, the first portion 1071 and the second portion 1072 of the semiconductor material layer 107 with a tubular structure may have a third diameter d3, which is larger than the second diameter d2 of the third portion 1073 of the semiconductor material layer 107.

As shown in FIGS. 2 to 7, according to an embodiment of the present disclosure, the DRAM cell structure 100 may include a second dielectric layer 108 disposed in a common electrode trench as a capacitance dielectric for a storage capacitor C. According to an embodiment of the present disclosure, the second dielectric layer 108 may be formed conformally along the trench wall of the common electrode trench. As shown in FIGS. 2 and 4, according to an embodiment of the present disclosure, the second dielectric layer 108 may contact the two second isolation material layers 103, the first gate layer 104, the second gate layer 105, and a second portion of the semiconductor material layer 107 in a second horizontal direction (x direction). Furthermore, as shown in FIGS. 2 and 5, according to an embodiment of the present disclosure, the second dielectric layer 108 may contact the second portion of the semiconductor material layer 107 in a first horizontal direction (y direction). The first horizontal direction, i.e., the y direction, may be perpendicular to the second horizontal direction, i.e., the x direction.

Furthermore, according to embodiments of the present disclosure, the material used to form the second dielectric layer 108 can be a high-K material. The high-K material can have a higher dielectric constant than silicon oxide. Silicon oxide can have a dielectric constant of about 3.9, and the second dielectric layer 108 can include a high-K material with a dielectric constant of about 4 or greater. According to embodiments of the present disclosure, the high-K material can include hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅), strontium titanium oxide (SrTiO₃), or combinations thereof.

As shown in FIGS. 2 to 7, according to embodiments of the present disclosure, the DRAM cell structure 100 may include an electrode layer 110 extending along the surface of the second dielectric layer 108 and filling a common electrode trench. According to embodiments of the present disclosure, the electrode layer 110 may correspond to the outer electrode of the storage capacitor C shown in FIG. 1, i.e., the common electrode of the storage capacitor C, and the source line SL. As shown in FIGS. 2 to 7, according to embodiments of the present disclosure, the electrode layer 110 corresponding to the outer electrode of the storage capacitor C and the source line SL may extend in a first horizontal direction (y direction) and run through the DRAM cell structure 100 in the vertical direction (z direction). According to embodiments of the present disclosure, the material used to form the electrode layer 110 may include titanium nitride (TiN), tantalum nitride (TaN), aluminum titanium carbide (TiAlC), aluminum (Al), copper (Au), titanium (Ti), palladium (Pd), molybdenum (Mo), platinum (Pt), tungsten (W), doped polycrystalline/amorphous silicon, indium tin oxide (ITO), indium zinc oxide (IZO), or combinations thereof. Therefore, according to embodiments of the present disclosure, the storage capacitor C of the DRAM cell structure 100 can be formed as a cylindrical capacitor.

Furthermore, although not shown in the figures, according to embodiments of the present disclosure, a third isolation material layer may be provided between the first gate layer 104 and the second gate layer 105 and the second dielectric layer 108 to reduce the parasitic capacitance and leakage current between the outer electrode (source line SL) of the storage capacitor and the gates G1 and G2 (i.e., the first and second word lines WLA and WLB) of the first and second transistors T1 and T2.

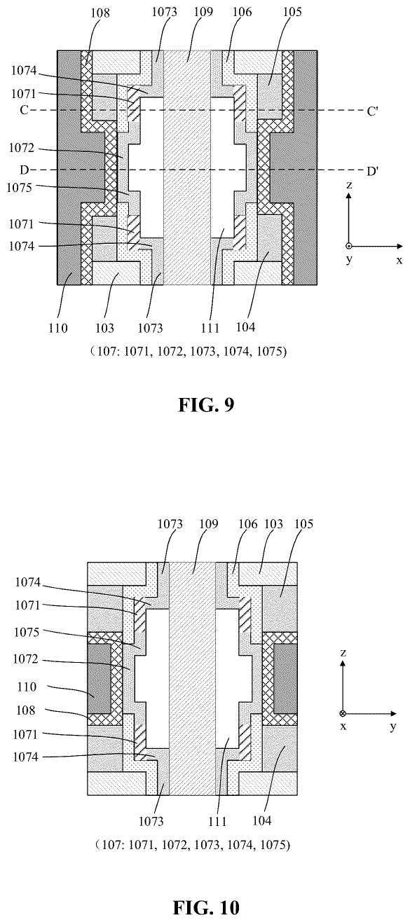

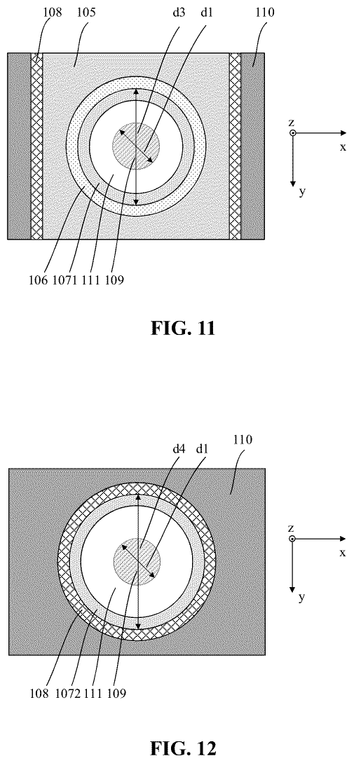

FIG. 8 is a top view illustrating a DRAM cell structure 100′ according to another embodiment of the present disclosure. FIG. 9 is a cross-sectional view illustrating a DRAM cell structure 100′ according to another embodiment of the present disclosure, taken along line AA′ in FIG. 8. FIG. 10 is a cross-sectional view illustrating a DRAM cell structure 100′ according to another embodiment of the present disclosure, taken along line BB′ in FIG. 8. FIG. 11 is a cross-sectional view illustrating a DRAM cell structure 100′ according to another embodiment of the present disclosure, taken along line CC′ in FIG. 9. FIG. 12 is a cross-sectional view illustrating a DRAM cell structure 100′ according to another embodiment of the present disclosure, taken along line DD′ in FIG. 9. Elements shown in FIGS. 8 to 12 that are the same as those shown in FIGS. 3 to 7 are indicated by the same reference numerals and will not be described repeatedly for the sake of brevity.

The difference between the DRAM cell structure 100′ shown in FIGS. 8 to 12 and the DRAM cell structure 100 shown in FIGS. 3 to 7 only lies in that, as shown in FIG. 12, the second portion 1072 of the semiconductor material layer 107 with a tubular structure of the DRAM cell structure 100′ has a fourth diameter d4, which is larger than the third diameter d3 of the first portion 1071 of the semiconductor material layer 107. Therefore, correspondingly, according to an embodiment of the present disclosure, as shown in FIGS. 9 and 10, the semiconductor material layer 107 with a tubular structure of the DRAM cell structure 100′ further includes a second horizontal connecting portion 1075 connecting the first portion 1071 and the second portion 1072.

Compared to the DRAM cell structure 100 shown in FIGS. 3 to 7, in the DRAM cell structure 100′ shown in FIGS. 8 to 12, the inner electrode of the storage capacitor C extends outward, which increases the effective overlap area between the inner electrode and outer electrode of the storage capacitor C, thereby increasing the capacitance value of the storage capacitor C.

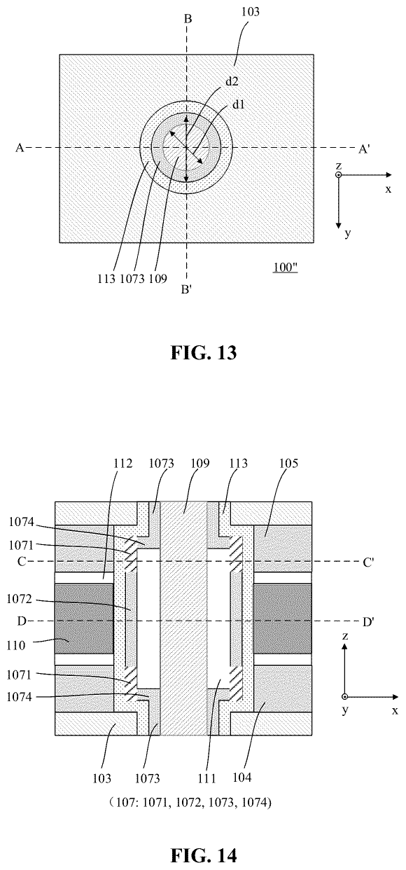

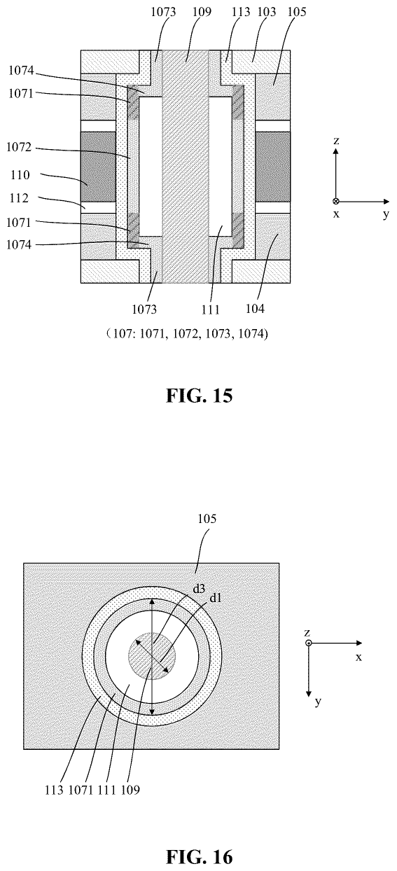

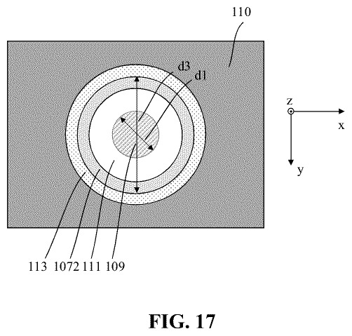

FIG. 13 is a top view illustrating a DRAM cell structure 100″ according to yet another embodiment of the present disclosure. FIG. 14 is a cross-sectional view of the DRAM cell structure 100″ according to yet another embodiment of the present disclosure, taken along line AA′ in FIG. 13. FIG. 15 is a cross-sectional view of the DRAM cell structure 100″ according to yet another embodiment of the present disclosure, taken along line BB′ in FIG. 13. FIG. 16 is a cross-sectional view of the DRAM cell structure 100″ according to yet another embodiment of the present disclosure, taken along line CC′ in FIG. 14. FIG. 17 is a cross-sectional view of the DRAM cell structure 100″ according to yet another embodiment of the present disclosure, taken along line DD′ in FIG. 14. Elements shown in FIGS. 13 to 17 that are the same as those shown in FIGS. 3 to 7 are indicated by the same reference numerals and will not be described repeatedly for the sake of brevity.

The difference between the DRAM cell structure 100″ shown in FIGS. 13 to 17 and the DRAM cell structure 100 shown in FIGS. 3 to 7 lies in that the DRAM cell structure 100″ omits the common electrode trench, and the gate dielectric of the first transistor T1 and the second transistor T2 and the capacitance dielectric of the storage capacitor C are formed by the same dielectric layer, namely the third dielectric layer 113. As shown in FIGS. 14 and 15, according to an embodiment of the present disclosure, the third dielectric layer 113 may be configured to have a tubular structure conformally surrounding the semiconductor layer 107.

According to embodiments of the present disclosure, the material used to form the third dielectric layer 113 may be a high-K material, for example, hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅), strontium titanium oxide (SrTiO₃), or combinations thereof.

Furthermore, as shown in FIGS. 14 and 15, according to an embodiment of the present disclosure, since the common electrode trench is omitted, a fourth isolation material layer 112 is disposed among the electrode layer 110 (corresponding to the outer electrode and source line SL of the storage capacitor C shown in FIG. 1) and the first gate layer 104 (corresponding to the gate G1 and first word line WLA of the first transistor T1 shown in FIG. 1) and the second gate layer 105 (corresponding to the gate G2 and second word line WLB of the second transistor T2 shown in FIG. 1), for achieving electrical isolation between the electrode layer 110 and the first gate layer 104 and the second gate layer 105. According to an embodiment of the present disclosure, the fourth isolation material layer 113 may be formed of the same or different isolation material as the first isolation material layer 111 and/or the second isolation material layer 103.

Therefore, according to the embodiments of the present disclosure, as shown in FIGS. 14, 15, and 17, in the DRAM cell structure 100″, since the source line SL (electrode layer 110) extends in the horizontal direction (x and y directions), the source line SL can be led out from the distal end in the horizontal direction (x and/or y directions). Furthermore, since the common electrode trench is omitted, and the first gate layer 104 and the second gate layer 105 also extend in the horizontal direction (x and y directions). Therefore, unlike the DRAM cell structure 100 described above with reference to FIGS. 3 to 7, in the DRAM cell structure 100″, in addition to the first horizontal direction (y direction), the first gate layer 104 and the second gate layer 105 can also be led out from the distal end in the second horizontal direction (x direction).

According to embodiments of the present disclosure, as shown in FIGS. 13 to 17, the DRAM cell structure 100″ can further simplify the structure and process, and reduce manufacturing costs.

Furthermore, according to embodiments of the present disclosure, a cavity may also be disposed in the first isolation material layer 111 in the DRAM cell structures 100 to 300.

According to embodiments of the present disclosure, a DRAM cell structure includes two transistors and a storage capacitor mirror-disposed in the vertical direction, wherein the inner electrode of the storage capacitor and the source/drain and channel regions of the two transistors are formed by the same semiconductor material layer. Therefore, it has advantages such as simple structure and good switching performance, and is beneficial for stacking in the vertical direction to form a three-dimensional multilayer memory array. In particular, this cell structure can utilize the parallel connection of two transistors to increase the on-state current of the selection transistor, thereby improving the switching speed performance of the memory cell; simultaneously, the storage capacitor can be completely isolated in the middle by the two transistors, which can prevent the stored information from being interfered with by external signals or adjacent cells, thereby improving the reliability of the memory cell.

Again, in particular, this cell structure solves the connection problem of the transistor source/drain and the inner electrode of the storage capacitor using a vertical structure. It is suitable for applying to three-dimensional vertical integration of multilayer DRAM cells. Moreover, the adoption of vertical structure is suitable for the one-time processing of multilayer DRAM cells, without the need for multiple epitaxial processes and processing techniques, resulting in low manufacturing costs.

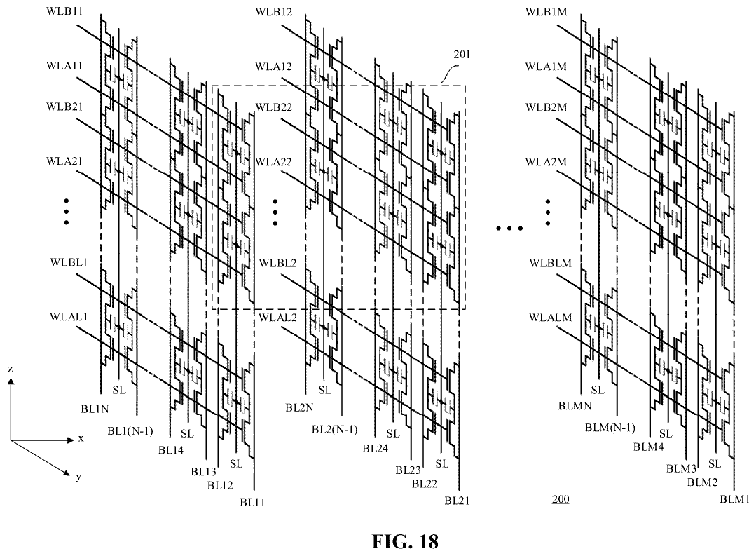

FIG. 18 is an equivalent circuit diagram illustrating a DRAM array structure 200 formed by the DRAM cell structure shown in FIG. 1 according to an embodiment of the present disclosure. As shown in FIG. 18, according to an embodiment of the present disclosure, the DRAM array structure 200 formed by the DRAM cell structure shown in FIG. 1 can be a three-dimensional DRAM array structure stacked in the vertical direction (z direction).

As shown in FIG. 18, according to an embodiment of the present disclosure, the DRAM array structure 200 may include a plurality of DRAM cell structures 100 as shown in FIG. 1. For clarity, certain reference numerals within each DRAM cell structure are omitted. According to an embodiment of the present disclosure, the plurality of DRAM cell structures are arranged in L layers, M rows, and N columns, where L, M, and N are all natural numbers greater than 1. Each of the plurality of DRAM cell structures herein included in the DRAM array structure 200 can be represented as Clmn, that is, the DRAM cell structure located in the m-th row, n-th column, and l-th layer of the DRAM array structure 200, where m, n, and l are natural numbers, and 1≤m≤M, 1≤n≤N, and 1≤l≤L. Furthermore, M herein represents the number of rows of DRAM cell structures in the DRAM array structure 200 along the first horizontal direction (y direction), N represents the number of columns of DRAM cell structures in the DRAM array structure 200 along the second horizontal direction (x direction), and L represents the number of layers of DRAM cell structures in the DRAM array structure 200 along the vertical direction (z direction).

According to embodiments of the present disclosure, the cell selection operation of the plurality of DRAM cell structures included in the DRAM array structure 200 can be performed by L×M first word lines WLA11 to WLALM, L×M second word lines WLB11 to WLBLM, and M×N bit lines BL11 to BLMN.

Therefore, as shown in FIG. 18, according to the embodiments of the present disclosure, in the DRAM array structure 200, each layer of the L layers of DRAM cell structures includes M rows and N columns, totaling M×N DRAM cell structures. Each row of the M rows of DRAM cell structure includes L layers and N columns, totaling L×N DRAM cell structures; and each column of the N columns of DRAM cell structure includes L layers and M rows, totaling L×M DRAM cell structures.

As described above with reference to FIGS. 1 to 7, each of the plurality of DRAM cell structures included in the DRAM array structure 200 may include: a first transistor and a second transistor, each having a channel with tubular structure and a gate surrounding the channel, disposed sequentially in the vertical direction and electrically connected in parallel; and a storage capacitor having a tubular structure, disposed in the vertical direction between the first transistor and the second transistor, with its inner electrode connected to the first source/drain of the first transistor and the second transistor.

Furthermore, as shown in FIG. 18, according to an embodiment of the present disclosure, the DRAM array structure 200 may further include M×N bit lines BL11 to BLMN, which extend respectively in the vertical direction within the tubular structure collectively formed by L first transistors and L second transistors, as well as L storage capacitor in the M rows and N columns of DRAM cell structure, and are respectively connected to the second source/drain of the L first transistors and L second transistors in the M rows and N columns of DRAM cell structure.

Furthermore, although not shown, according to embodiments of the present disclosure, in each row of the M rows of DRAM array structure, L first word lines WLA1m to WLALm can be connected to L second word lines WLB1m to WLBLm, respectively. For example, as shown in FIG. 18, in the first row of the DRAM array structure, the first word line WLA11 can be connected to the second word line WLB11, the first word line WLA21 can be connected to the second word line WLB21, and so on, until the first word line WLAL1 can be connected to the second word line WLBL1. According to embodiments of the present disclosure, in each row of the M rows of DRAM array structure, the corresponding connection of L first word lines and L second word lines can be implemented from the distal end outside the array. Since the paired first word line WLAlm and second word line WLBlm extending along the first horizontal direction (y direction) herein can be connected together, they can be collectively referred to as word line WL and given the same numeral as the corresponding first word line WLAlm and second word line WLBlm, i.e., WLlm. At this time, according to the embodiments of the present disclosure, the cell selection operation of the plurality of DRAM cell structures included in the DRAM array structure 200 can be performed by L×M word lines WL11 to WLLM and M×N bit lines BL11 to BLMN.

Furthermore, according to embodiments of the present disclosure, the DRAM array structure 200 may further include L source lines SL corresponding to L layers of DRAM cell structures, which extend along a first horizontal direction (y direction) and are respectively connected to the outer electrode of the storage capacitor in the L layers of DRAM cell structures. Additionally, as shown in FIG. 18, according to embodiments of the present disclosure, the L source lines SL can be connected together by a common electrode trench disposed between bit lines that run through the entire DRAM array structure 200 in the vertical direction (z direction), in which case the source lines SL also extend in the vertical direction (z direction). Although not shown, according to alternative embodiments of the present disclosure, the L source lines SL may also be connected together simply outside the DRAM array structure 200, either collectively or in groups, while omitting the common electrode trench.

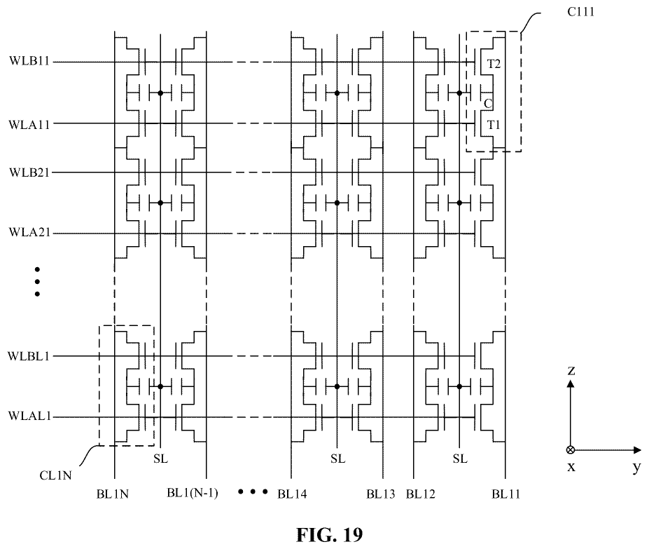

FIG. 19 is an equivalent circuit diagram illustrating the DRAM cell structures C111 to CL1N of the first row of the DRAM array structure 200 according to an embodiment of the present disclosure shown in FIG. 18. As shown in FIG. 19, the first row, first column, first layer of DRAM cell structure C111 is disposed at the intersection of the first row, first column of bit line BL11 extending in the vertical direction (z direction) and the first layer of word line (first word line WLA11 and second word line WLB11) extending in the first horizontal direction (y direction). Similarly, the first row of the DRAM array structure 200 shown in FIG. 19 includes N×L DRAM cell structures C111 to CL1N.

As described above with reference to FIG. 1, according to an embodiment of the present disclosure, each of the plurality of DRAM cell structures constituting the DRAM array structure 200, for example, the DRAM cell structure C111 shown in FIG. 19, includes a first transistor T1, a second transistor T2, and a storage capacitor C.

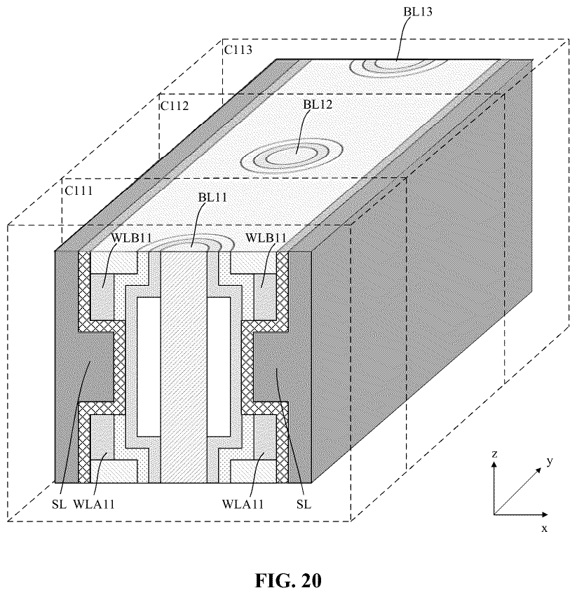

FIG. 20 is a schematic perspective view illustrating the first layer, first row of DRAM cell structure of the DRAM array structure 200 according to an embodiment of the present disclosure, as shown in FIG. 18. As shown in FIG. 20, in the first layer, first row of DRAM cell structure of the DRAM array structure, the first layer, first row of word line WL11 (first word line WLA11 and second word line WLB11) can extend along a first horizontal direction (y direction), and the first row of bit lines (only BL11 to BL13 are shown) can extend along the vertical direction (z direction). According to an embodiment of the present disclosure, the source lines SL of the first layer of DRAM cell structure can extend along the first horizontal direction (y direction). Furthermore, as shown in FIG. 20, the source lines SL can also be connected together with the source lines SL of other layers in a common electrode trench extending along the vertical direction (z direction).

Furthermore, as shown in FIGS. 18 to 20, according to an embodiment of the present disclosure, the bit line BLmn in the m-th row and n-th column can be connected to the second source/drain of the L first transistors and L second transistors in the m-th row and n-th column DRAM cell structure of the DRAM array structure 200, for performing a cell selection operation on the m-th row and n-th column DRAM cell structure.

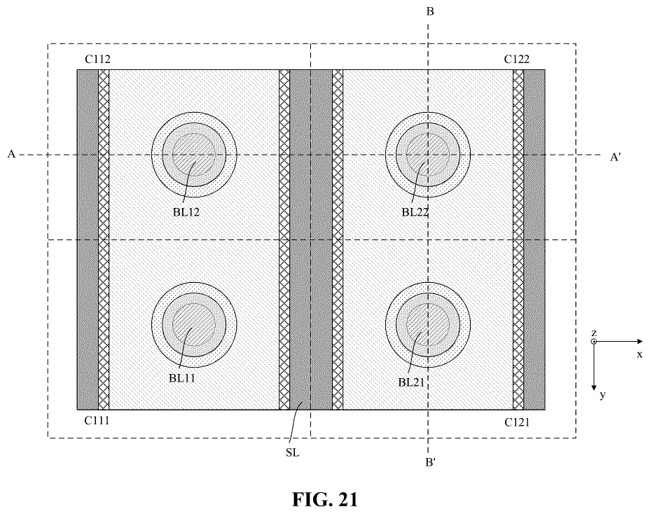

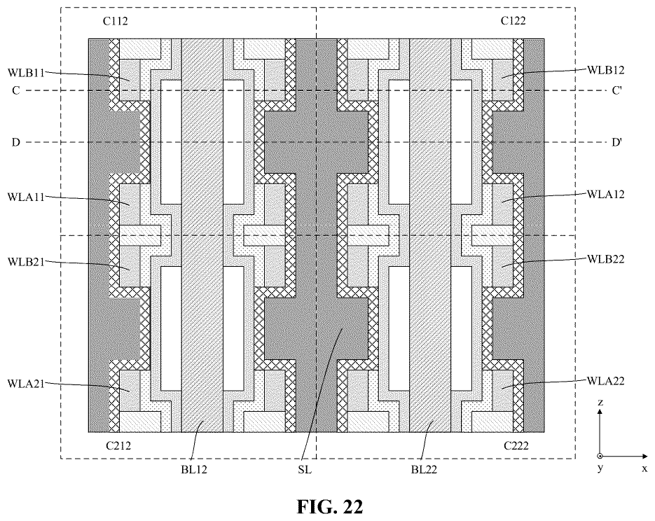

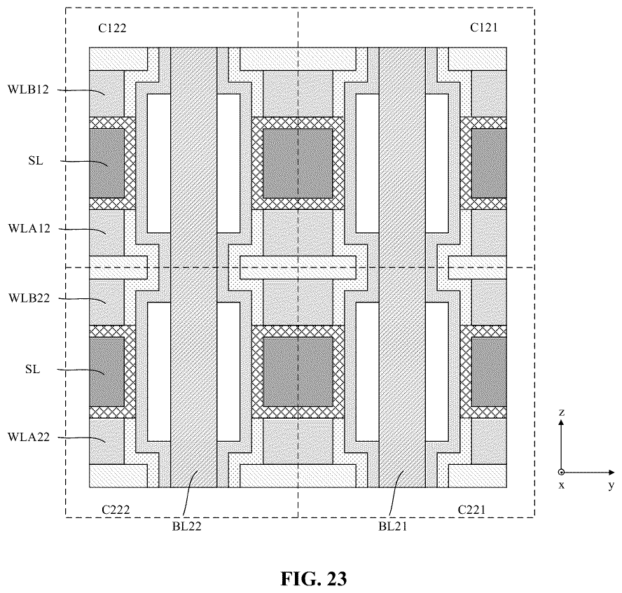

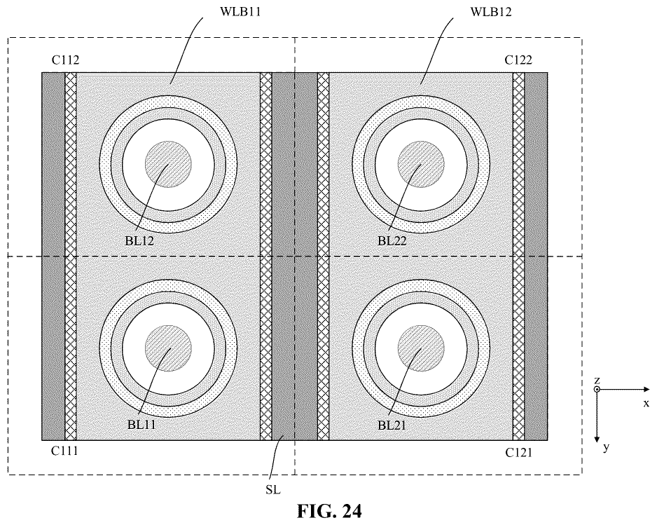

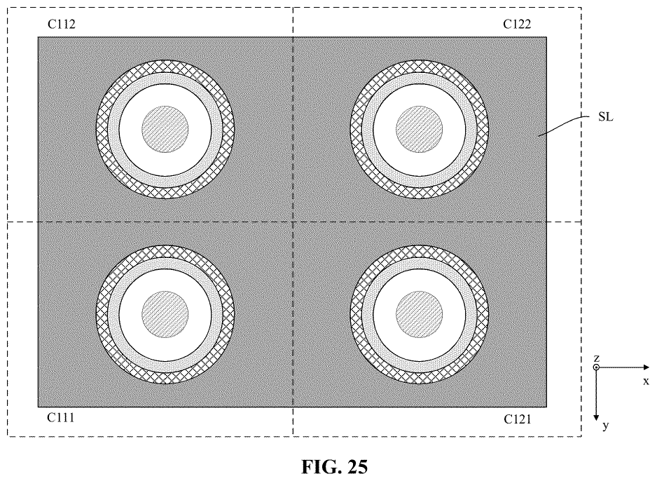

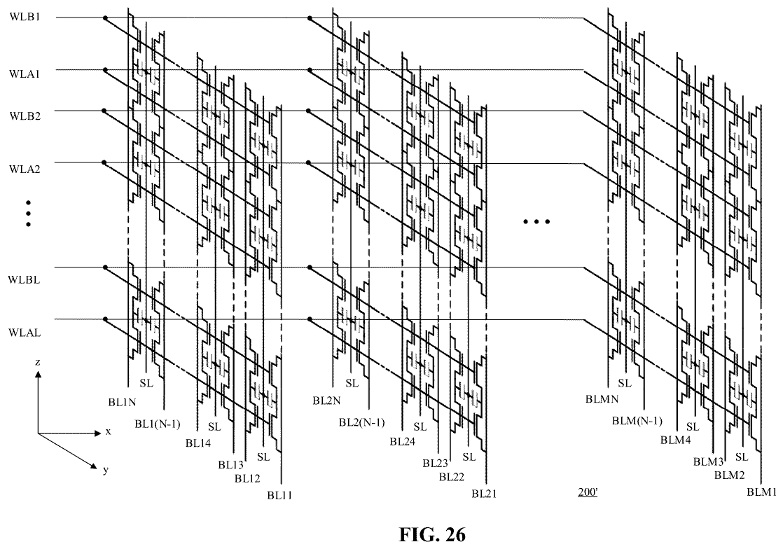

FIG. 21 is a top view illustrating a partial DRAM array structure 201 of the DRAM array structure 200 according to an embodiment of the present disclosure shown in FIG. 18. FIG. 22 is a cross-sectional view illustrating a DRAM array structure 201 according to an embodiment of the present disclosure, taken along line AA′ in FIG. 21. FIG. 23 is a cross-sectional view illustrating a DRAM array structure 201 according to an embodiment of the present disclosure, taken along line BB′ in FIG. 21. FIG. 24 is a cross-sectional view illustrating a DRAM array structure 201 according to an embodiment of the present disclosure, taken along line CC′ in FIG. 22. FIG. 25 is a cross-sectional view illustrating a DRAM array structure 201 according to an embodiment of the present disclosure, taken along line DD′ in FIG. 22.

It should be noted that FIGS. 21 to 25 exemplarily illustrate a partial DRAM array structure 201 as part of the DRAM array structure 200 shown in FIG. 18, which includes DRAM cell structures C111, C112, C121, C122, C211, C212, C221, and C222 of the first row and first column of the first layer to the second row and second column of the second layer. These eight DRAM cell structures are arranged in two rows, two columns, and two layers.

According to embodiments of the present disclosure, the M rows and N columns of bit lines BL11 to BLMN of the DRAM array structure 200, can extend in the vertical direction (z direction) and be arranged in an M×N matrix form in the first horizontal direction (y direction) and the second horizontal direction (x direction). Furthermore, according to embodiments of the present disclosure, the L layers of DRAM cell structures in the DRAM array structure 200 are stacked sequentially in the vertical direction, and each layer of DRAM cell structure includes M×N DRAM cell structures.

Specifically, as shown in FIGS. 21 to 25, the four bit lines BL11, BL12, BL21, and BL22 in two rows and two columns can extend in the vertical direction (z direction) and be arranged in a 2×2 matrix in the first horizontal direction (y direction) and the second horizontal direction (x direction). Furthermore, as shown in FIGS. 22 and 23, the first layer of DRAM cell structures C111, C112, C121, and C122 are stacked on top of the second layer of DRAM cell structures C211, C212, C121, and C222.

As shown in FIGS. 21 and 22, the first word line WLA11 of the first row of the first layer is connected to the gate of the first transistor in the first row of the first layer of DRAM cell structures C111 and C112, and the second word line WLB11 of the first layer is connected to the gate of the second transistor of the first row of the first layer of DRAM cell structures C111 and C112. Similarly, the first word line WLA12 of the second row of the first layer is connected to the gate of the first transistor in the second row of the first layer of DRAM cell structures C121 and C122, and the second word line WLB12 of the second row of the first layer is connected to the gate of the second transistor in the second row of the first layer of DRAM cell structures C121 and C122. Similarly, the first word line WLA21 in the first row of the second layer is connected to the gate of the first transistor in the first row of the second layer of DRAM cell structures C211 and C212, and the second word line WLB21 in the first row of the second layer is connected to the gate of the second transistor in the first row of the second layer of DRAM cell structures C211 and C212. Similarly, the first word line WLA22 of the second row of the second layer is connected to the gate of the first transistor in the second row of the second layer of DRAM cell structure C221 and C222, and the second word line WLB22 of the second row of the second layer is connected to the gate of the second transistor in the second row of the second layer of DRAM cell structure C221 and C222.

As shown in FIGS. 21 to 25, four bit lines BL11, BL12, BL21, and BL22 are respectively formed in four bit line holes extending through in the vertical direction (z direction) the DRAM array structure. Specifically, bit line BL11 of the first row and first column extends in the vertical direction inside the tubular structure formed by the first transistor and second transistor and the storage capacitor in the first row and first column of DRAM cell structures C111 and C211, and connects to the second source/drain of the first transistor and second transistor in the first row and first column of DRAM cell structures C111 and C211. Similarly, bit line BL12 of the first row and second column extends in the vertical direction inside the tubular structure formed by the first transistor and second transistor and the storage capacitor in the first row and second column of DRAM cell structures C112 and C212, and connects to the second source/drain of the first transistor and second transistor in the first row and second column of DRAM cell structures C112 and C212. Similarly, bit line BL21 of the second row and first column extends in the vertical direction inside the tubular structure formed by the first transistor and second transistor and the storage capacitor in the second row and first column of DRAM cell structures C121 and C221, and connects to the second source/drain of the first transistor and second transistor in the second row and first column of DRAM cell structures C121 and C221. Similarly, bit line BL22 in the second row and second column extends in the vertical direction inside the tubular structure formed by the first transistor and second transistor and the storage capacitor in the second row and second column DRAM cell structures C122 and C222, and connects to the second source/drain of the first transistor and second transistor in the second row and second column DRAM cell structures C122 and C222.

According to embodiments of the present disclosure, in each of the M rows×N columns of the DRAM cell structure, the first source/drain and second source/drain, the channel region of the first transistor and the second transistor, and the inner electrode of the storage capacitor are formed by the same semiconductor material layer. That is, according to embodiments of the present disclosure, in each of the M×N bit line holes extending through the L layers of DRAM cell structures in the vertical direction (z direction), the first source/drain and second source/drain, the channel region of the first transistor and the second transistor, and the inner electrode of the storage capacitor in the L layers of DRAM cell structures are formed by the same the semiconductor material layer with a tubular structure. In other words, the semiconductor material layer with a tubular structure extends in the vertical direction (z direction) through the entire DRAM array structure 200.

Specifically, as shown in FIGS. 21 to 25, the first source/drain and second source/drain, channel regions of the first transistor and the second transistor, and inner electrode of the storage capacitor in the first layer of DRAM cell structure C111 and the second layer of DRAM cell structure C211 connected to the first row, first column of bit line BL11 are formed by the same semiconductor material layer. Similarly, the first source/drain and second source/drain, channel regions of the first transistor and the second transistor, and inner electrode of the storage capacitor in the first layer of DRAM cell structure C112 and the second layer of DRAM cell structure C212 connected to the first row and second column of bit line BL12 are formed by the same semiconductor material layer. Similarly, the first source/drain and second source/drain, channel regions of the first transistor and the second transistor, and inner electrode of the storage capacitor in the first layer of DRAM cell structure C121 and the second layer of DRAM cell structure C221 connected to the second row and first column of bit line BL21 are formed by the same semiconductor material layer. Similarly, the first source/drain and the second source/drain, the channel region of the first transistor and the second transistor and the inner electrode of the storage capacitor in the first layer of DRAM cell structure C122 and the second layer of DRAM cell structure C222 connected to the second row and second column of bit line BL22 are formed by the same semiconductor material layer.

According to embodiments of the present disclosure, the common electrode trench can extend in the first horizontal direction (y direction) and run through the L layers of DRAM array structure in the vertical direction (z direction). In this case, the L source lines SL corresponding to the L layers of DRAM cell structures can be connected together in the vertical direction (z direction). Furthermore, according to embodiments of the present disclosure, adjacent rows of DRAM cell structures in the second horizontal direction (x direction) can share the common electrode trench. Additionally, as described above, the capacitance dielectric and outer electrode of the storage capacitor in each DRAM cell structure of the DRAM array structure 200 can be disposed in the common electrode trench.

Alternatively, according to embodiments of the present disclosure, the common electrode trench may be omitted in the DRAM array structure 200. In this case, the source line SL may extend only in the first horizontal direction (y direction) and be connected together either collectively or in groups outside the DRAM array structure 200.

FIG. 26 is an equivalent circuit diagram illustrating a DRAM array structure 200′ with an alternative configuration of word line according to an embodiment of the present disclosure. In FIG. 26, the same components as in FIG. 18 are indicated by the same reference numerals, and their repeated descriptions will be omitted.

Referring to FIG. 26 in conjunction with FIG. 18, the DRAM array structure 200′ shown in FIG. 26 differs from the DRAM array structure 200 shown in FIG. 18 in that, in each layer of the L layers of DRAM cell structures, M first word lines WLA11 to WLA1M can be connected together to form a common first word line WLA1 of the l-th layer, and M second word lines WLB11 to WLB1M can be connected together to form a common second word line WLB1 of the l-th layer. Specifically, as shown in FIG. 26, the first word lines WLA11 to WLA1M of the first layer of DRAM cell structure are connected together to form a common first word line WLA1 of the first layer, and the second word lines WLB11 to WLB1M of the first layer of DRAM cell structure are connected together to form a common second word line WLB1 of the first layer. Similarly, the first word lines WLA21 to WLA2M of the second layer of DRAM cell structure are connected together to form the second layer of common first word line WLA2, and the second word lines WLB21 to WLB2M of the second layer of DRAM cell structure are connected together to form the first layer of common second word line WLB2. This continues until the first word lines WLAL1 to WLALM of the L-th layer of DRAM cell structure are connected together to form the L-th layer of common first word line WLAL, and the second word lines WLBL1 to WLBLM of the Lth layer of DRAM cell structure are connected together to form the Lth layer of common second word line WLBL.

At this time, according to the embodiments of the present disclosure, the DRAM array structure 200′ has L first word lines WLA1 to WLAL, L second word lines WLB1 to WLBL, and M×N bit lines BL11 to BLMN. According to the embodiments of the present disclosure, the selection operation of each DRAM cell structure Clmn in the DRAM array structure 200′ can be implemented by the first word line WLA1, the second word line WLB1, and the bit line BLmn.

Furthermore, according to embodiments of the present disclosure, in each row of the M rows of DRAM array structure, where L first word lines WLA1m to WLALm are respectively connected to L second word lines WLB1m to WLBLm, the DRAM array structure 200′ shown in FIG. 26 can be further simplified to L word lines WL1 to WLL. In this case, according to embodiments of the present disclosure, the selection operation of each DRAM cell structure Clmn in the DRAM array structure 200′ can be implemented by word lines WL1 and bit line BLmn.

Therefore, the DRAM array structure 200′ shown in FIG. 26 can simplify the word line configuration compared to the DRAM array structure 200 shown in FIG. 18.

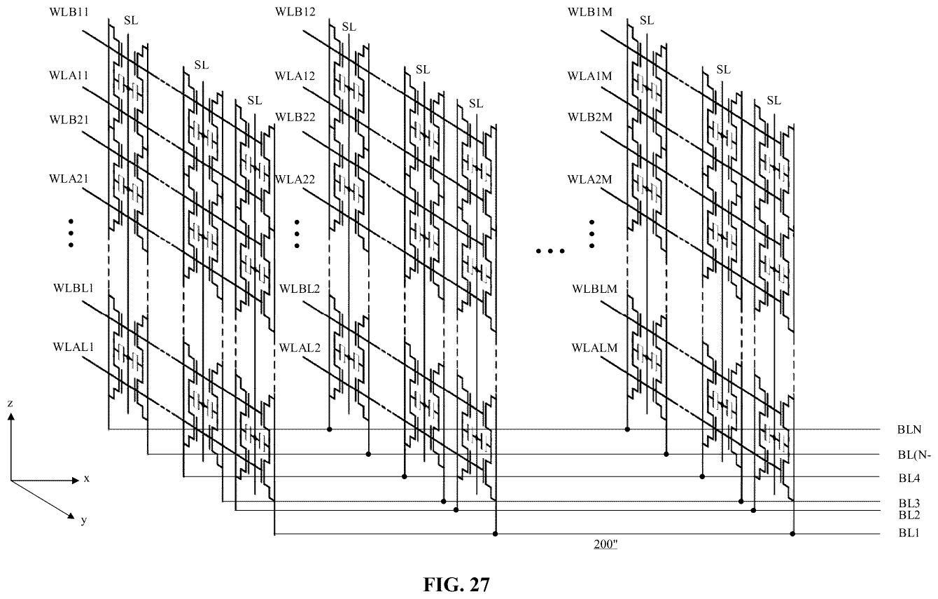

FIG. 27 is an equivalent circuit diagram illustrating a DRAM array structure 200″ with an alternative configuration of bit line according to an embodiment of the present disclosure. In FIG. 27, the same components as in FIG. 18 are indicated by the same reference numerals, and their repeated descriptions will be omitted.

Referring to FIG. 27 in conjunction with FIG. 18, the DRAM array structure 200″ shown in FIG. 27 differs from the DRAM array structure 200″ shown in FIG. 18 in that, in each column of the N columns of DRAM cell structure, M bit lines BL1n to BLMn can be connected together to form the common bit line BLn of the nth column. Specifically, as shown in FIG. 27, bit lines BL11 to BLM1 of the first column of the DRAM cell structure are connected together to form the common bit line BL1 of the first column. Similarly, bit lines BL12 to BLM2 of the second column of the DRAM cell structure are connected together to form the common bit line BL2 of the first column. Similarly, bit lines BL1N to BLMN of the Nth column of the DRAM cell structure are connected together to form the common bit line BLN of the Nth column.

At this time, according to the embodiments of the present disclosure, the DRAM array structure 200″ has L×M first word lines WLA11 to WLALM, L×M second word lines WLB11 to WLBLM, and N bit lines BL1 to BLN. According to the embodiments of the present disclosure, the selection operation of each DRAM cell structure Clmn in the DRAM array structure 200″ can be implemented by the first word line WLAlm, the second word line WLBlm, and the bit line BLn.

Furthermore, according to embodiments of the present disclosure, in each row of the M rows of DRAM array structure, where L first word lines WLA1m to WLALm are respectively connected to L second word lines WLB1m to WLBLm, the DRAM array structure 200″ shown in FIG. 27 can be further simplified to L×M word lines WL11 to WLLM. In this case, according to embodiments of the present disclosure, the selection operation of each DRAM cell structure Clmn in the DRAM array structure 200″ can be implemented by word lines WLlm and bit line BLn.

Therefore, the DRAM array structure 200″ shown in FIG. 27 can simplify the bit line configuration compared to the DRAM array structure 200 shown in FIG. 18.

According to embodiments of the present disclosure, since the DRAM array structure 200 is a three-dimensional vertically integrated DRAM array structure, it can be stacked on a circuit substrate including various circuits to realize a vertically integrated semiconductor device.

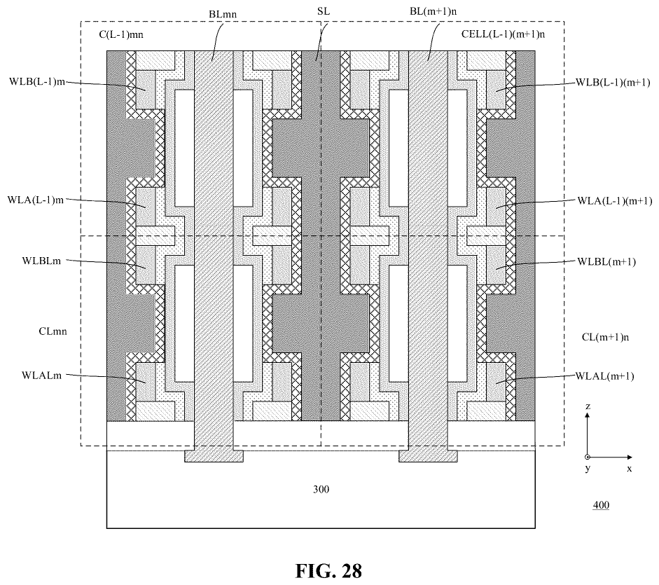

FIG. 28 is a schematic cross-sectional view illustrating a semiconductor device 400 according to an embodiment of the present disclosure. According to an embodiment of the present disclosure, the semiconductor device 400 may include a circuit substrate 300 and a DRAM array structure 200 disposed on the circuit substrate 300. Although FIG. 28 only shows a partial DRAM array structure as the DRAM array structure 200 shown in FIG. 18, namely DRAM cell structures CLmn, C(L−1)nm, CL(m+1)n, and C(L−1)(m+1)n stack on the circuit substrate 300, those skilled in the art will recognize that the entire DRAM array structure 200 may be stacked on the circuit substrate 300.

As shown in FIG. 28, according to an embodiment of the present disclosure, the circuit substrate 300 may be a semiconductor substrate on which a plurality of circuits may be fabricated by semiconductor manufacturing processes, for example, standard CMOS processes. According to an embodiment of the present disclosure, the L layers of DRAM cell structures of the DRAM array structure 200 may be stacked on the circuit substrate 300 in the vertical direction (z direction), thereby achieving system-level three-dimensional vertical integration.

According to embodiments of the present disclosure, a plurality of circuits on the circuit substrate 300 can be connected to the DRAM array structure 200 by, for example, wires and vias extending in the vertical direction (z direction).

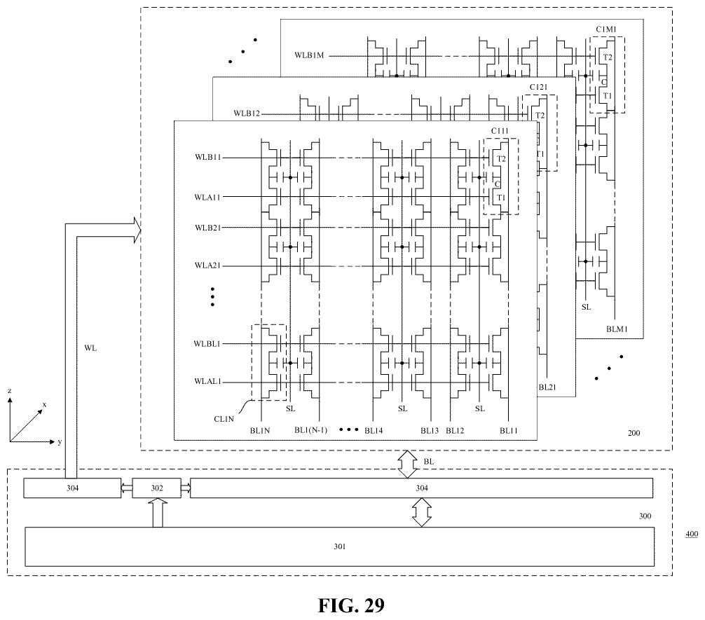

FIG. 29 is a schematic block diagram illustrating a semiconductor device 400 according to an embodiment of the present disclosure.

As shown in FIG. 29, according to an embodiment of the present disclosure, the plurality of circuits included in the circuit substrate 300 can be a memory controller circuit 302, a word line circuit 303, and a bit line circuit 304.

According to embodiments of the present disclosure, the memory controller circuit 302 may be the main management circuit of the DRAM array structure 200, used to process all instructions related to read and write operations of the DRAM array structure 200. Furthermore, the memory controller circuit 302 is also used to refresh the DRAM cell structure, because the data stored in the DRAM cell structure gradually disappears over time, so it needs to be refreshed periodically to maintain data integrity.

According to embodiments of the present disclosure, word line circuit 303 is used to select a group of DRAM cell structures connected to a specified word line in the DRAM array structure 200. For example, when data needs to be read from or written to the DRAM array structure, word line circuit 303 is activated to select a group of DRAM cell structures connected to the specified word line. Furthermore, bit line circuit 304 is used to select a specific DRAM cell structure in the group of DRAM cell structures connected to the specified word line. When word line circuit 303 selects a group of DRAM cell structures, bit line circuit 304 can select a bit line connected to one DRAM cell structure of the DRAM cell structures in that group, thereby determining the precise location of the data. Additionally, bit line circuit 304 is also used to transmit data during read and write operations.

According to embodiments of the present disclosure, word line circuit 303 can be connected to word line WL of DRAM array structure 200, and bit line circuit 304 can be connected to bit line BL of DRAM array structure 200.

According to embodiments of the present disclosure, when the DRAM array structure 200 shown in FIG. 18 is stacked on the circuit substrate 300, the word line circuit 303 can be connected to L×M word lines WL11 to WLLM (L×M first word lines WLA11 to WLALM and L×M second word lines WLB11 to WLBLM), and the bit line circuit 304 can be connected to M×N bit lines BL11 to BLMN. Furthermore, according to embodiments of the present disclosure, when the DRAM array structure 200′ shown in FIG. 26 is stacked on the circuit substrate 300, the word line circuit 303 can be connected to L word lines WL1 to WLL (L first word lines WLA1 to WLAL and L second word lines WLB1 to WLBL), and the bit line circuit 304 can be connected to M×N bit lines BL11 to BLMN. Furthermore, according to embodiments of the present disclosure, when the DRAM array structure 200″ shown in FIG. 27 is stacked on the circuit substrate 300, the word line circuit 303 can be connected to L×M word lines WL11 to WLLM (L×M first word lines WLA11 to WLALM and L×M second word lines WLB11 to WLBLM), and the bit line circuit 304 can be connected to N bit lines BL1 to BLN.

According to embodiments of the present disclosure, since word line WL extends in the first horizontal direction (y direction) in the three-dimensional DRAM array structures (200, 200′, and 200″) according to embodiments of the present disclosure, word line circuit 303 can be connected to the word line WL of the three-dimensional DRAM array structure by wires and vias extending in the vertical direction (z direction). Furthermore, according to embodiments of the present disclosure, since bit line BL extends in the vertical direction (z direction) in the three-dimensional DRAM array structures (200, 200′, and 200″) according to embodiments of the present disclosure, bit line circuit 304 can be directly connected to bit line BL.

Furthermore, according to embodiments of the present disclosure, the plurality of circuits included in the circuit substrate 300 may further include a circuit 301, which may be a processor circuit or a memory interface circuit. According to embodiments of the present disclosure, circuit 301 may be connected to memory controller circuit 302 for sending address, instruction, and/or data information to it, and may be connected to bit line circuit 304 for transmitting or receiving data from it.

According to embodiments of the present disclosure, when circuit 301 is a processor circuit, semiconductor device 400 can be a computing system, and when circuit 301 is a memory interface circuit, semiconductor device 400 can be a memory system.

The DRAM cell structure constituting the DRAM array structure according to the present disclosure includes two transistors and a storage capacitor mirror-disposed in the vertical direction, wherein the inner electrode of the storage capacitor and the source/drain and channel regions of the two transistors are formed by the same semiconductor material layer, thus having the advantages of simple structure and good switching performance.

In particular, this cell structure solves the connection problem of the source and drain of the transistor and the inner electrode of the storage capacitor using a vertical structure. It is suitable for three-dimensional vertical integration of multi-layer cells. Moreover, the adoption of vertical structure is suitable for the one-time processing of multi-layer cells, without the need for multiple epitaxial processes and processing techniques, resulting in low manufacturing costs.

Furthermore, the DRAM array structure according to the present disclosure can achieve three-dimensional vertical integration by stacking multiple layers of DRAM cells, thereby increasing integration density. Additionally, the DRAM array structure according to the present disclosure can be stacked on a circuit substrate including a plurality of circuits, thus enabling system-level three-dimensional vertical integration and significantly reducing the area overhead of the circuit system.

Although many details are contained herein, these details should not be interpreted as limitations on the scope of the present disclosure or what may be claimed, but rather as descriptions of features that may be specific to particular embodiments. Certain features described herein in the context of separate embodiments may also be implemented in combination in a single embodiment. Conversely, various features described in the context of a single embodiment may also be implemented in multiple embodiments separately or in any suitable subcombination. Furthermore, although features may be described above as functioning in certain combinations, and even initially declared as such, in some cases one or more features in a combination may be deleted from a claimed combination, and a claimed combination may involve subcombinations or variations of subcombinations.

1. A DRAM cell structure, comprising:
a first transistor and a second transistor, each having a channel with tubular structure and a gate surrounding the channel, and sequentially disposed in a vertical direction and electrically connected in parallel;
a storage capacitor having a tubular structure, disposed in the vertical direction between the first and second transistors, having an inner electrode connected to first sources/drains of the first and second transistors, and having an outer electrode connected to a source line; and
a bit line extending in the vertical direction within the tubular structure collectively formed by the first and second transistors as well the storage capacitor, and connecting to second sources/drains of the first and second transistors.

2. The DRAM cell structure of claim 1, wherein
a first word line extends along a first horizontal direction and is connected to the gate of the first transistor, and
a second word line extends along the first horizontal direction and is connected to the gate of the second transistor, and the first word line and the second word line overlap in the vertical direction.

3. The DRAM cell structure of claim 1, wherein
source/drain regions and channel regions of the first and second transistors, as well as the inner electrode of the storage capacitor, are formed by the same semiconductor material layer.

4. The DRAM cell structure of claim 3, wherein
the semiconductor material layer includes:
first portions, forming the channel regions of the first and second transistors;
a second portion, between the first portions, forming the first source/drain regions of the first and second transistors and the inner electrode of the storage capacitor;
third portions, forming the second source/drain regions of the first and second transistors; and
first horizontal connecting portions connecting the first portions and the third portions,
wherein the diameter of the second portion of the semiconductor material layer is equal to the diameter of the first portions of the semiconductor material layer,
wherein the diameter of the first portions of the semiconductor material layer is larger than the diameter of the third portions of the semiconductor material layer, and
wherein the first portions and second portion of the semiconductor material layer have different doping types, doping concentrations, and/or atomic composition ratios.

5. The DRAM cell structure of claim 3, wherein
the semiconductor material layer includes:
first portions, forming the channel regions of the first and second transistors;
a second portion, between the first portions, forming the first source/drain regions of the first and second transistors and the inner electrode of the storage capacitor;
third portions, forming the second source/drain regions of the first and second transistors;
first horizontal connecting portions, connecting the first portions and the third portions; and
second horizontal connecting portions, connecting the first portions and the second portion,
wherein the diameter of the second portion of the semiconductor material layer is larger than the diameter of the first portions of the semiconductor material layer, and
wherein the diameter of the first portions of the semiconductor material layer is larger than the diameter of the third portions of the semiconductor material layer, and
wherein the first portions and second portion of the semiconductor material layer have different doping types, doping concentrations, and/or atomic composition ratios.

6. The DRAM cell structure of claim 3, wherein
the semiconductor material layer includes a single layer of IGZO or a stack of multiple layers of IGZO with different proportions.

7. The DRAM cell structure of claim 4, further comprising:
a bit line hole extending through the DRAM cell structure in the vertical direction; and
a common electrode trench, extending in the first horizontal direction and extending through the DRAM cell structure in the vertical direction.

8. The DRAM cell structure of claim 7, wherein
the bit line and the semiconductor material layer are disposed in the bit line hole, and the semiconductor material layer surrounds the bit line, and
the third portions of the semiconductor material layer are in contact with the bit line, and the first portions and second portion of the semiconductor material layer are separated from the bit line by a first isolation material layer surrounding the bit line.

9. The DRAM cell structure of claim 7, wherein
the capacitance dielectric and outer electrode of the storage capacitor are disposed in the common electrode trench, and the capacitance dielectric is in direct contact with the second portion of the semiconductor material layer.

10. The DRAM cell structure of claim 9, wherein
the source line extends in the common electrode trench along the first horizontal direction and the vertical direction.

11. The DRAM cell structure of claim 3, wherein
the gate dielectric of the first and second transistors and the capacitance dielectric of the storage capacitor are formed by the same dielectric layer.

12. The DRAM cell structure of claim 11, wherein the source line extends along the first horizontal direction.

13. A three-dimensional DRAM array structure, comprising:
a plurality of DRAM cell structures arranged in L layers, M rows, and N columns, wherein L, M, and N are natural numbers greater than 1, each of the plurality of DRAM cell structures including:
a first transistor and a second transistor, each having a channel with tubular structure and a gate surrounding the channel, and sequentially disposed in a vertical direction and electrically connected in parallel, and
a storage capacitor having a tubular structure, disposed in the vertical direction between the first and second transistors, having an inner electrode connected to first source/drains of the first and second transistors, and having an outer electrode connected to a source line;
M×N bit lines extending respectively along the vertical direction within the tubular structure collectively formed by the first and second transistors as well as the storage capacitor in the M rows and N columns of the DRAM cell structures, and respectively connecting to second source/drains of the first and second transistors in the M rows and N columns of the DRAM cell structures;
L×M first word lines extending along a first horizontal direction and respectively connecting to the gates of the first transistors in the L layers and M rows of the DRAM cell structures; and
L×M second word lines extending along the first horizontal direction and respectively connecting to the gates of the second transistors in the L layers and M rows of the DRAM cell structures.

14. The three-dimensional DRAM array structure of claim 13, further comprising:
M×N bit line holes extending through the DRAM array structure in the vertical direction, wherein the M×N bit lines are respectively disposed in the M×N bit line holes.

15. The three-dimensional DRAM array structure of claim 13, wherein,
the L layers of the DRAM cell structures are stacked sequentially in the vertical direction, and
L first word lines and L second word lines are stacked sequentially alternately in the vertical direction in the M rows of the DRAM cell structures.

16. The three-dimensional DRAM array structure of claim 13, wherein,
in each row of the M rows of the DRAM cell structures, L first word lines are connected to L second word lines respectively.

17. The three-dimensional DRAM array structure of claim 13, wherein,
in each layer of the L layers of the DRAM cell structures, M first word lines are connected together, and M second word lines are connected together.

18. The three-dimensional DRAM array structure of claim 13, wherein,
in each column of the N columns of the DRAM cell structures, M bit lines are connected together.

19. The three-dimensional DRAM array structure of claim 13, further comprising:
L source lines, each corresponding to the L layers of the DRAM cell structures, extending along the first horizontal direction and respectively connecting to the outer electrode of the storage capacitor in the L layers of the DRAM cell structures; and
common electrode trenches extending in the first horizontal direction and extending through the DRAM array structure in the vertical direction, and disposed between adjacent rows of the DRAM cell structures,
wherein the L source lines are connected together through the common electrode trenches.

20. A semiconductor device, comprising:
a three-dimensional DRAM array structure, wherein the three-dimensional DRAM array structure comprises:
a plurality of DRAM cell structures arranged in L layers, M rows, and N columns, wherein L, M, and N are natural numbers greater than 1, each of the plurality of DRAM cell structures including:
a first transistor and a second transistor, each having a channel with tubular structure and a gate surrounding the channel, and sequentially disposed in a vertical direction and electrically connected in parallel, and
a storage capacitor having a tubular structure, disposed in the vertical direction between the first and second transistors, having an inner electrode connected to first source/drains of the first and second transistors, and having an outer electrode connected to a source line;
M×N bit lines extending respectively along the vertical direction within the tubular structure collectively formed by the first and second transistors as well as the storage capacitor in the M rows and N columns of the DRAM cell structures, and respectively connecting to second source/drains of the first and second transistors in the M rows and N columns of the DRAM cell structures;
L×M first word lines extending along a first horizontal direction and respectively connecting to the gates of the first transistors in the L layers and M rows of the DRAM cell structures; and
L×M second word lines extending along the first horizontal direction and respectively connecting to the gates of the second transistors in the L layers and M rows of the DRAM cell structures; and
a circuit substrate, comprising a plurality of circuits, wherein the three-dimensional DRAM array structure is disposed on the circuit substrate.
